(19) United States
(12) Patent Application Publication
(10) Pub. No.: US 2020/0266324 A1
(43) Pub. Date: Aug. 20, 2020

(54) METHOD AND STRUCTURE OF BONDING A LED WITH A SUBSTRATE

(71) Applicant: Prilit Optronics, Inc., Tainan City (TW)

(72) Inventors: Biing-Seng Wu, Tainan City (TW); Hsing Ying Lee, Tainan City (TW); Chao-Wen Wu, Tainan City (TW)

(21) Appl. No.: 16/280,734

(22) Filed: Feb. 20, 2019

(51) Int. Cl. H01L 33/62

(52) U.S. Cl. CPC H01L 33/62; H01L 33/36; H01L 2933/0066

(57) ABSTRACT

A method of bonding a light-emitting diode (LED) with a substrate includes providing a LED disposed on a bottom surface of a LED substrate; forming a first isolating layer entirely on a substrate; forming a second isolating layer on the first isolating layer within a first area corresponding to an N-type contact pad of the LED; forming a first conductive layer on the second isolating layer within the first area; forming a second conductive layer on the first isolating layer within a second area corresponding to a P-type contact pad of the LED; and bonding the LED to the substrate by connecting the N-type contact pad to the first conductive layer within the first area, and connecting the P-type contact pad to the second conductive layer within the second area.

### BACKGROUND OF THE INVENTION

### 1. Field of the Invention

The present invention generally relates to a light-emitting diode (LED), and more particularly to a method of bonding a LED with a substrate.

### 2. Description of Related Art

A light-emitting diode (LED) is a two-electrode semiconductor light source. The LED includes a p-n junction diode that emits light when activated by recombining electrons with electron holes within the device.

Flip chip technique is commonly adopted to interconnect the LEDs with a glass substrate. The LED is flipped over so that its top faces down, followed by aligning pads of the LED with corresponding pads on the glass substrate to complete the interconnect.

However, the top surfaces of the N-type contact and the P-type contact are generally not at the same level. For example, the P-type contact may be higher than the N-type contact with 1-3 micrometers. Accordingly, the flip bonding of the LED with the glass substrate is not balanced, and the N-type contact and the P-type contact may not be well adapted to the glass substrate.

In other to overcome this drawback, it is conventional to thicken the N-type contact, however, with additional process steps, more material, further difficulty and higher cost. A need has thus arisen to propose a novel scheme for flip bonding a LED with a substrate in a simple and economic manner.

### SUMMARY OF THE INVENTION

In view of the foregoing, it is an object of the embodiment of the present invention to provide a method of bonding a light-emitting diode (LED) with a substrate such that the flip bonding of the LED with the substrate may be well balanced.

According to one embodiment, a structure of bonding a light-emitting diode (LED) with a substrate includes a first isolating layer entirely formed on a substrate; a second isolating layer formed on the first isolating layer within a first area corresponding to an N-type contact pad of the LED; a first conductive layer formed on the second isolating layer within the first area; a second conductive layer formed on the first isolating layer within a second area corresponding to a P-type contact pad of the LED; and a LED, disposed on a bottom surface of a LED substrate, bonded to the substrate by connecting the N-type contact pad to the first conductive layer within the first area, and connecting the P-type contact pad to the second conductive layer within the second area.

In another embodiment, a structure of bonding a light-emitting diode (LED) with a substrate includes an isolating layer entirely formed on a substrate, the isolating layer having a recess within a second area corresponding to a P-type contact pad of the LED; a first conductive layer formed on the isolating layer out of the recess and within a first area corresponding to an N-type contact pad of the LED; a second conductive layer formed on the isolating layer in the recess and within the second area; and a LED, disposed on a bottom surface of a LED substrate, bonded to the substrate by connecting the N-type contact pad to the first conductive layer within the first area, and connecting the P-type contact pad to the second conductive layer within the second area.

### BRIEF DESCRIPTION OF THE DRAWINGS

FIG. 1A to FIG. 1D show cross-sectional views illustrating a method of bonding a light-emitting diode (LED) with a substrate according to a first embodiment of the present invention; and

FIG. 2A to FIG. 2D show cross-sectional views illustrating a method of bonding a light-emitting diode (LED) with a substrate according to a second embodiment of the present invention.

### DETAILED DESCRIPTION OF THE INVENTION

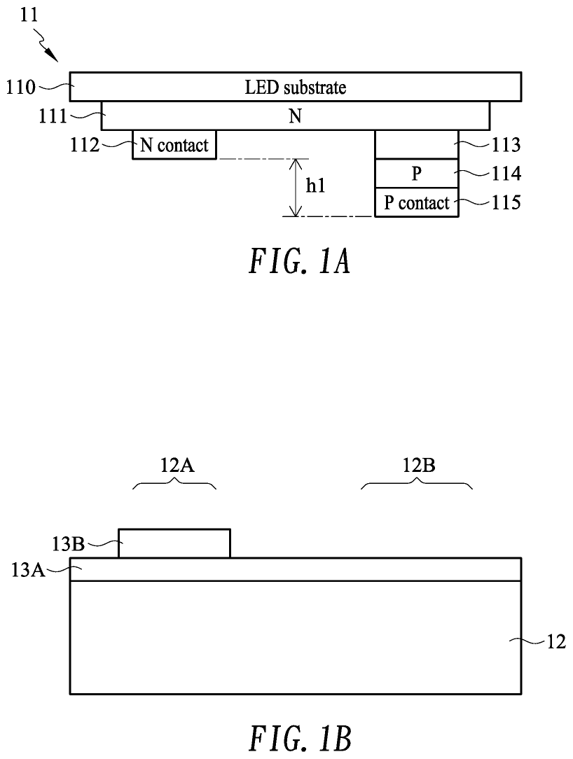

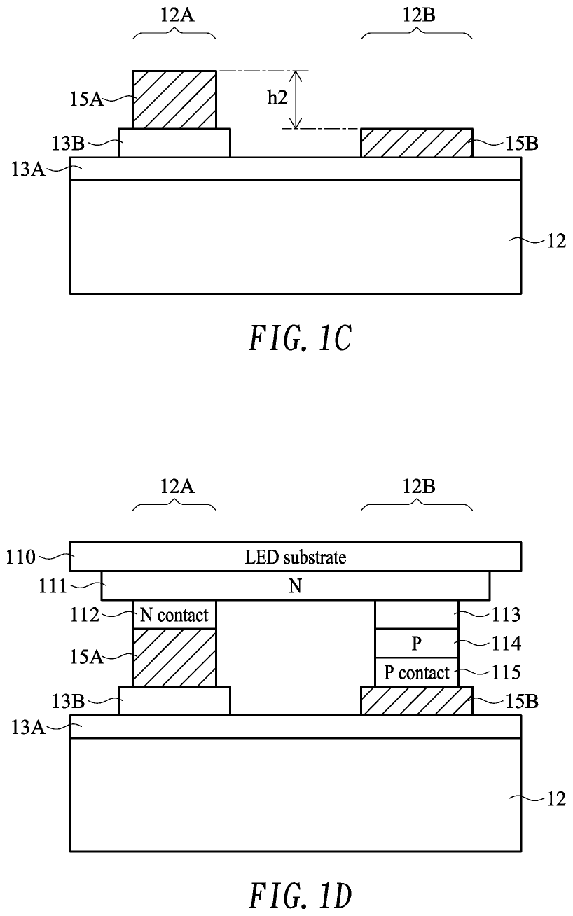

FIG. 1A to FIG. 1D show cross-sectional views illustrating a method of bonding a light-emitting diode (LED) 11 with a substrate 12 according to a first embodiment of the present invention.

Referring to FIG. 1A, a (flipped) LED 11 that is disposed on a bottom surface of a LED substrate 110 (e.g., sapphire, gallium arsenide (GaAs), silicon carbide (SC) or other suitable material) is provided. Specifically, the LED 11 may include an N-type layer 111 disposed on a bottom surface of the LED substrate 110, and an N-type contact pad 112 disposed on a bottom surface of the N-type layer 111. The LED 11 may include a potential well 113 such as multiple quantum well (MQW) disposed on the bottom surface of the N-type layer 111. The LED 11 may include a P-type layer 114 disposed on a bottom surface of the potential well 113, and a P-type contact pad 115 disposed on a bottom surface of the P-type layer 114. It is noted that a first height difference between (the bottom surface of) the N-type contact pad 112 and (the bottom surface of) the P-type contact pad 115 is denoted by h1.

Referring to FIG. 1B, a substrate 12 (e.g., glass substrate or other suitable material) is provided. A first isolating layer 13A is entirely formed on a top surface of the substrate 12, for example, by coating process. Next, a second isolating layer 13B is formed on the first isolating layer 13A within a first area 12A corresponding to the N-type contact pad 112. Accordingly, the second isolating layer 13B within the first area 12A is higher than the first isolating layer 13A within a second area 12B corresponding to the P-type contact pad 115. The first isolating layer 13A and the second isolating layer 13B of the embodiment may include electrically isolating material such as silicon nitride Si₃N₄, silicon oxide SiO₂ or other suitable material.

Referring to FIG. 1C, a first conductive layer 15A is formed on the second isolating layer 13B within the first area 12A, and a second conductive layer 15B is formed on the first isolating layer 13A within the second area 12B, for example, by coating process. The first conductive layer 15A and the second conductive layer 15B of the embodiment may include electrically conductive material such as metal. The thickness of the first conductive layer 15A and the thickness of the second conductive layer 15B may not necessarily be the same. It is appreciated that the first conductive layer 15A and the second conductive layer 15B may be formed simultaneously or individually. It is noted that a second height difference between (the top surface of) the first conductive layer 15A and (the top surface of) the second conductive layer 15B is denoted by h2. According to one aspect of the embodiment, the first height difference h1 (FIG. 1A) is approximately equal to the second height difference h2 (FIG. 1C).

Referring to FIG. 1D, the LED 11 as shown in FIG. 1A is (flip) bonded to the substrate 12 to result in the structure shown in FIG. 1D. Specifically, (the bottom surface of) the N-type contact pad 112 is connected to (the top surface of) the first conductive layer 15A within the first area 12A, and (the bottom surface of) the P-type contact pad 115 is connected to (the top surface of) the second conductive layer 15B within the second area 12B. As the first height difference h1 (between the N-type contact pad 112 and the P-type contact pad 115) and the second height difference h2 (between the first conductive layer 15A and the second conductive layer 15B) are approximately the same, the flip bonding of the LED 11 with the substrate 12 may be well balanced. Therefore, the N-type contact pad 112 may be well adapted to the first conductive layer 15A, and the P-type contact pad 115 may be well adapted to the second conductive layer 15B.

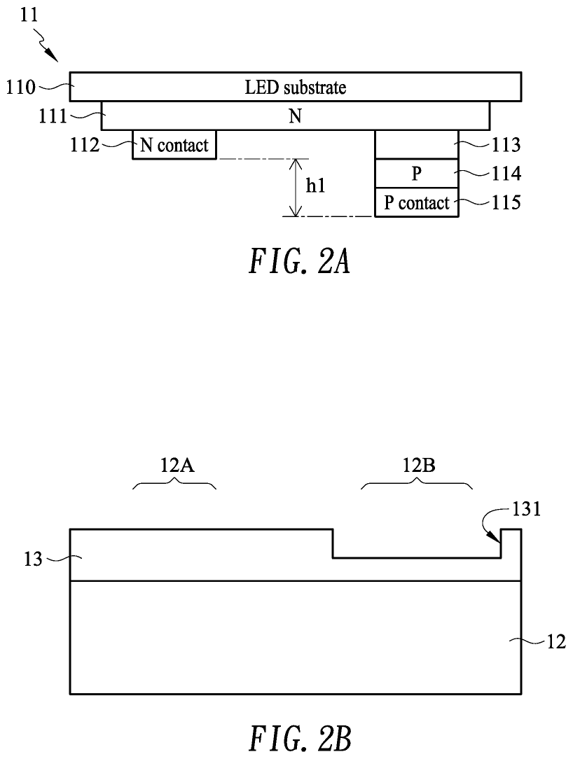

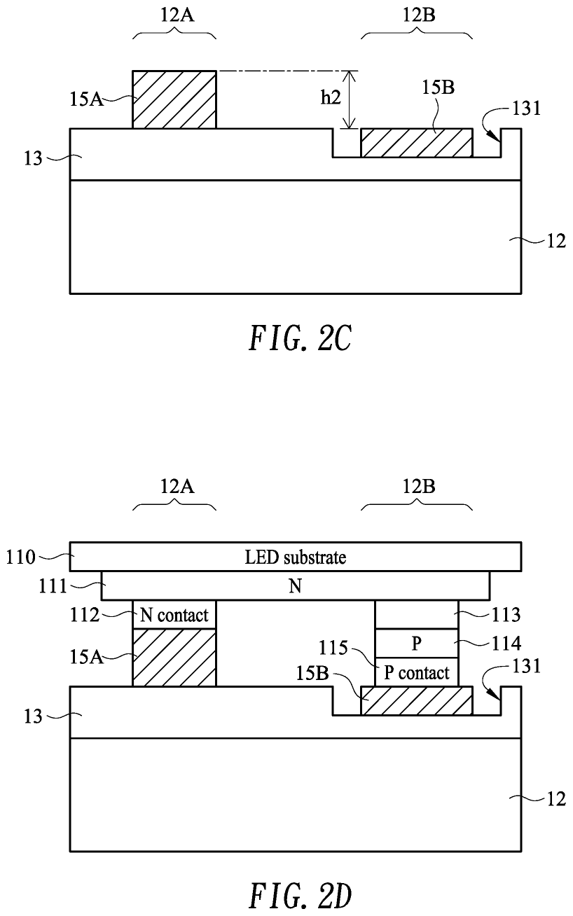

FIG. 2A to FIG. 2D show cross-sectional views illustrating a method of bonding a light-emitting diode (LED) 11 with a substrate 12 according to a second embodiment of the present invention.

Referring to FIG. 2A, a (flipped) LED 11 that is disposed on a bottom surface of a LED substrate 110 (e.g., sapphire, gallium arsenide (GaAs), silicon carbide (SC) or other suitable material) is provided. Specifically, the LED 11 may include an N-type layer 111 disposed on a bottom surface of the LED substrate 110, and an N-type contact pad 112 disposed on a bottom surface of the N-type layer 111. The LED 11 may include a potential well 113 such as multiple quantum well (MQW) disposed on the bottom surface of the N-type layer 111. The LED 11 may include a P-type layer 114 disposed on a bottom surface of the potential well 113, and a P-type contact pad 115 disposed on a bottom surface of the P-type layer 114. It is noted that a first height difference between (the bottom surface of) the N-type contact pad 112 and (the bottom surface of) the P-type contact pad 115 is denoted by h1.

Referring to FIG. 2B, a substrate 12 (e.g., glass substrate or other suitable material) is provided. An isolating layer 13 is entirely formed on a top surface of the substrate 12, for example, by coating process. The isolating layer 13 of the embodiment may include electrically isolating material such as silicon nitride Si₃N₄, silicon oxide SiO₂ or other suitable material. Next, the isolating layer 13 is subjected to (partial) etching to result in a recess 131 within a second area 12B corresponding to the P-type contact pad 115. Accordingly, the isolating layer 13 within a first area 12A (corresponding to the N-type contact pad 112) is higher than the isolating layer 13 within the second area 12B corresponding to the P-type contact pad 115.

Referring to FIG. 2C, a first conductive layer 15A is formed on the isolating layer 13 out of the recess 131 within the first area 12A, and a second conductive layer 15B is formed on the isolating layer 13 in the recess 131 within the second area 12B, for example, by coating process. The first conductive layer 15A and the second conductive layer 15B of the embodiment may include electrically conductive material such as metal. The thickness of the first conductive layer 15A and the thickness of the second conductive layer 15B may not necessarily be the same. It is appreciated that the first conductive layer 15A and the second conductive layer 15B may be formed simultaneously or individually. It is noted that a second height difference between (the top surface of) the first conductive layer 15A and (the top surface of) the second conductive layer 15B is denoted by h2. According to one aspect of the embodiment, the first height difference h1 (FIG. 2A) is approximately equal to the second height difference h2 (FIG. 2C).

Referring to FIG. 2D, the LED 11 as shown in FIG. 2A is (flip) bonded to the substrate 12 to result in the structure shown in FIG. 2D. Specifically, (the bottom surface of) the N-type contact pad 112 is connected to (the top surface of) the first conductive layer 15A within the first area 12A, and (the bottom surface of) the P-type contact pad 115 is connected to (the top surface of) the second conductive layer 15B within the second area 12B. As the first height difference h1 (between the N-type contact pad 112 and the P-type contact pad 115) and the second height difference h2 (between the first conductive layer 15A and the second conductive layer 15B) are approximately the same, the flip bonding of the LED 11 with the substrate 12 may be well balanced. Therefore, the N-type contact pad 112 may be well adapted to the first conductive layer 15A, and the P-type contact pad 115 may be well adapted to the second conductive layer 15B.

Although specific embodiments have been illustrated and described, it will be appreciated by those skilled in the art that various modifications may be made without departing from the scope of the present invention, which is intended to be limited solely by the appended claims.

What is claimed is:

1. A method of bonding a light-emitting diode (LED) with a substrate, comprising:
providing a LED disposed on a bottom surface of a LED substrate;
providing a substrate;
forming a first isolating layer entirely on the substrate;
forming a second isolating layer on the first isolating layer within a first area corresponding to an N-type contact pad of the LED;
forming a first conductive layer on the second isolating layer within the first area;
forming a second conductive layer on the first isolating layer within a second area corresponding to a P-type contact pad of the LED; and
bonding the LED to the substrate by connecting the N-type contact pad to the first conductive layer within the first area, and connecting the P-type contact pad to the second conductive layer within the second area.

2. The method of claim 1, wherein the LED comprises:
an N-type layer disposed on the bottom surface of the LED substrate;
the N-type contact pad disposed on a bottom surface of the N-type layer;
a potential well disposed on the bottom surface of the N-type layer;
a P-type layer disposed on a bottom surface of the potential well; and
the P-type contact pad disposed on a bottom surface of the P-type layer.

3. The method of claim 2, wherein a first height difference between the N-type contact pad and the P-type contact pad is approximately equal to a second height difference between the first conductive layer and the second conductive layer.

4. The method of claim 1, wherein the substrate comprises glass.

5. The method of claim 1, wherein the first isolating layer and the second isolating layer comprise electrically isolating material, and the first conductive layer and the second conductive layer comprise electrically conductive material.

6. A method of bonding a light-emitting diode (LED) with a substrate, comprising:
providing a LED disposed on a bottom surface of a LED substrate;
providing a substrate;
forming an isolating layer entirely on the substrate;
partially etching the isolating layer to result in a recess within a second area corresponding to a P-type contact pad of the LED;
forming a first conductive layer on the isolating layer out of the recess and within a first area corresponding to an N-type contact pad of the LED;
forming a second conductive layer on the first isolating layer in the recess and within the second area; and
bonding the LED to the substrate by connecting the N-type contact pad to the first conductive layer within the first area, and connecting the P-type contact pad to the second conductive layer within the second area.

7. The method of claim 6, wherein the LED comprises:
an N-type layer disposed on the bottom surface of the LED substrate;
the N-type contact pad disposed on a bottom surface of the N-type layer;
a potential well disposed on the bottom surface of the N-type layer;
a P-type layer disposed on a bottom surface of the potential well; and
the P-type contact pad disposed on a bottom surface of the P-type layer.

8. The method of claim 7, wherein a first height difference between the N-type contact pad and the P-type contact pad is approximately equal to a second height difference between the first conductive layer and the second conductive layer.

9. The method of claim 6, wherein the substrate comprises glass.

10. The method of claim 6, wherein the isolating layer comprises electrically isolating material, and the first conductive layer and the second conductive layer comprise electrically conductive material.

11. A structure of bonding a light-emitting diode (LED) with a substrate, comprising:
a first isolating layer entirely formed on the substrate;
a second isolating layer formed on the first isolating layer within a first area corresponding to an N-type contact pad of the LED;
a first conductive layer formed on the second isolating layer within the first area;
a second conductive layer formed on the first isolating layer within a second area corresponding to a P-type contact pad of the LED; and
the LED, disposed on a bottom surface of a LED substrate, bonded to the substrate by connecting the N-type contact pad to the first conductive layer within the first area, and connecting the P-type contact pad to the second conductive layer within the second area.

12. The structure of claim 11, wherein the LED comprises:
an N-type layer disposed on the bottom surface of the LED substrate;
the N-type contact pad disposed on a bottom surface of the N-type layer;
a potential well disposed on the bottom surface of the N-type layer;
a P-type layer disposed on a bottom surface of the potential well; and
the P-type contact pad disposed on a bottom surface of the P-type layer.

13. The structure of claim 12, wherein a first height difference between the N-type contact pad and the P-type contact pad is approximately equal to a second height difference between the first conductive layer and the second conductive layer.

14. The structure of claim 11, wherein the substrate comprises glass.

15. The structure of claim 11, wherein the first isolating layer and the second isolating layer comprise electrically isolating material, and the first conductive layer and the second conductive layer comprise electrically conductive material.

16. A structure of bonding a light-emitting diode (LED) with a substrate, comprising:
an isolating layer entirely formed on the substrate, the isolating layer having a recess within a second area corresponding to a P-type contact pad of the LED;
a first conductive layer formed on the isolating layer out of the recess and within a first area corresponding to an N-type contact pad of the LED;
a second conductive layer formed on the isolating layer in the recess and within the second area; and
the LED, disposed on a bottom surface of a LED substrate, bonded to the substrate by connecting the N-type contact pad to the first conductive layer within the first area, and connecting the P-type contact pad to the second conductive layer within the second area.

17. The structure of claim 16, wherein the LED comprises:
an N-type layer disposed on the bottom surface of the LED substrate;
the N-type contact pad disposed on a bottom surface of the N-type layer;
a potential well disposed on the bottom surface of the N-type layer;
a P-type layer disposed on a bottom surface of the potential well; and
the P-type contact pad disposed on a bottom surface of the P-type layer.

18. The structure of claim 17, wherein a first height difference between the N-type contact pad and the P-type contact pad is approximately equal to a second height difference between the first conductive layer and the second conductive layer.

19. The structure of claim 16, wherein the substrate comprises glass.

20. The structure of claim 16, wherein the isolating layer comprises electrically isolating material, and the first conductive layer and the second conductive layer comprise electrically conductive material.
